(19) United States
(12) Patent Application Publication
(10) Pub. No.: US 2026/0171356 A1
(43) Pub. Date: Jun. 18, 2026

(54) MULTI-CHARGED PARTICLE BEAM WRITING METHOD, AND MULTI-CHARGED PARTICLE BEAM WRITING APPARATUS

(71) Applicant: NuFlare Technology, Inc., Yokohama-shi (JP)

(72) Inventor: Hiroshi MATSUMOTO, Yokohama-shi (JP)

(73) Assignee: NuFlare Technology, Inc., Yokohama-shi (JP)

(21) Appl. No.: 19/366,668

(22) Filed: Oct. 23, 2025

(30) Foreign Application Priority Data
Dec. 12, 2024 (JP) 2024-217732

(51) Int. Cl. H01J 37/304; H01J 37/317

(52) U.S. Cl. CPC H01J 37/304; H01J 37/3177; H01J 2237/31764; H01J 2237/31774

(57) ABSTRACT

According to one aspect of the present invention, a multi-charged particle beam writing method includes assigning, to an irradiation unit region assigned one group of a plurality of groups in a plurality of irradiation unit regions, at least one sub shot which has been preset according to either one of an irradiation time set for an irradiation unit region concerned and a value calculated based on the irradiation time, in a plurality of sub shots each having one of a plurality of sub irradiation time obtained by dividing a maximum irradiation time for one shot, and assigning, to an irradiation unit region assigned another group in the plurality of groups, at least one sub shot which includes a sub shot other than the at least one sub shot having been set for the irradiation unit region assigned the one group in the same pixel-set.

### CROSS-REFERENCE TO RELATED APPLICATION

This application is based upon and claims the benefit of priority from prior Japanese Patent Application No. 2024-217732 filed on Dec. 12, 2024 in Japan, the entire contents of which are incorporated herein by reference.

### BACKGROUND OF THE INVENTION

### Field of the Invention

Embodiments of the present invention relate to a multi-charged particle beam writing method and a multi-charged particle beam writing apparatus.

### Description of Related Art

The lithography technique which advances miniaturization of semiconductor devices is extremely important as a unique process in which patterns are formed in semiconductor manufacturing. In recent years, with high integration of LSI, the line width (critical dimension) necessary for semiconductor device circuits is decreasing year by year. The electron beam writing technique, which intrinsically has excellent resolution, is used for writing or “drawing” patterns on a wafer exposure mask, wafer, and the like with electron beams.

For example, as a known example of employing the electron beam writing technique, there is a writing apparatus using multiple electron beams. Since writing with multiple electron beams can apply a lot of beams at a time, the writing throughput can be greatly increased compared to writing with a single electron beam. For example, a writing apparatus employing the multiple-beam system forms multiple beams by letting an electron beam emitted from an electron gun pass through a mask having a plurality of holes, performs blanking control for each beam, reduces each unblocked beam to generate a reduced mask image by an optical system, and deflects, by a deflector, a reduced beam to be applied to a desired position on a target object or “sample”.

With recent trend of miniaturization of patterns, the writing process has been shifted to the low sensitivity resist. As the resist sensitivity becomes lower, irradiation with a higher dose becomes necessary along with it. In order to perform irradiation with a high dose without increasing the writing time, it is needed to enhance the total beam current of multiple beams by increasing the number of beams and the current density used in multi-beam writing. However, in the multi-beam writing, if the total beam current becomes large, beam blur occurs due to the Coulomb effect, which degrades the resolution performance.

Therefore, it is desirable to reduce the average current of ON beams during a shot cycle by decreasing the number of beams simultaneously becoming ON.

There is disclosed a method where the maximum irradiation time settable for one shot is divided into a plurality of divided shots of a plurality of irradiation time, and a shot of the irradiation time for each pixel is performed by combining the divided shots (e.g., refer to Japanese Patent Application Laid-open (JP-A) No. 2017-191900). Furthermore, a method is disclosed where multiple beams are divided into a plurality of groups, and irradiation is performed while shifting the irradiation time of each group, thereby reducing the total beam current flowing at the same timing. However, in that case, shots are needed to be performed twice while shifting the irradiation timing for obtaining the amount of one shot.

### BRIEF SUMMARY OF THE INVENTION

According to one aspect of the present invention, a multi-charged particle beam writing method includes
assigning one of a plurality of groups to each irradiation unit region of a plurality of irradiation unit regions which are unit regions obtained by dividing a writing region of a target object to be irradiated with each beam of multiple charged particle beams, and for which a plurality of pixel-sets each composed of two and more irradiation unit regions are set in advance such that each irradiation unit region in a same pixel-set of the plurality of pixel-sets belongs to a group different from each other in the plurality of groups, and that a plurality of irradiation unit regions to be irradiated with each shot of the multiple charged particle beams include irradiation unit regions of different groups of the plurality of groups;
assigning, to an irradiation unit region assigned one group of the plurality of groups in the plurality of irradiation unit regions, at least one sub shot which has been preset according to either one of an irradiation time set for an irradiation unit region concerned in the plurality of irradiation unit regions and a value calculated based on the irradiation time, in a plurality of sub shots each having one of a plurality of sub irradiation time obtained by dividing a maximum irradiation time for one shot, and assigning, to an irradiation unit region assigned another group in the plurality of groups, at least one sub shot which includes a sub shot other than the at least one sub shot having been set for the irradiation unit region assigned the one group in the same pixel-set; and
writing, with respect to the each shot, a pattern on the target object using the multiple charged particle beams by applying at least one sub shot assigned to the each irradiation unit region of the plurality of irradiation unit regions to be irradiated with the multiple charged particle beams, wherein
with respect to each pixel-set of the plurality of pixel-sets, the at least one sub shot is assigned to the another group such that a value calculated based on a total of sub irradiation time of a preset at least one sub shot assigned to the one group and a total of sub irradiation time of the at least one sub shot assigned to the another group becomes a pixel-set irradiation time which is set for each irradiation unit region in a pixel-set concerned.

According to another aspect of the present invention, a multi-charged particle beam writing apparatus includes
a group assignment processing circuit configured to assign one of a plurality of groups to each irradiation unit region of a plurality of irradiation unit regions which are unit regions obtained by dividing a writing region of a target object to be irradiated with each beam of multiple charged particle beams, and for which a plurality of pixel-sets each composed of two and more irradiation unit regions are set in advance such that each irradiation unit region in a same pixel-set of the plurality of pixel-sets belongs to a group different from each other in the plurality of groups, and that a plurality of irradiation unit regions to be irradiated with each shot of the multiple charged particle beams include irradiation unit regions of different groups of the plurality of groups;
a sub shot assignment processing circuit configured to assign, to an irradiation unit region assigned one group of the plurality of groups in the plurality of irradiation unit regions, at least one sub shot which has been preset according to either one of an irradiation time set for an irradiation unit region concerned in the plurality of irradiation unit regions and a value calculated based on the irradiation time, in a plurality of sub shots each having one of a plurality of sub irradiation time obtained by dividing a maximum irradiation time for one shot, and to assign, to an irradiation unit region assigned another group in the plurality of groups, at least one sub shot which includes a sub shot other than the at least one sub shot having been set for the irradiation unit region assigned the one group in the same pixel-set; and
a writing mechanism configured to write, with respect to the each shot, a pattern on the target object using the multiple charged particle beams by applying at least one sub shot assigned to the each irradiation unit region of the plurality of irradiation unit regions to be irradiated with the multiple charged particle beams, wherein
the sub shot assignment processing circuit assigns, with respect to each pixel-set of the plurality of pixel-sets, the at least one sub shot to the another group such that a value calculated based on a total of sub irradiation time of a preset at least one sub shot assigned to the one group and a total of sub irradiation time of the at least one sub shot assigned to the another group becomes a pixel-set irradiation time which is set for each irradiation unit region in a pixel-set concerned.

### BRIEF DESCRIPTION OF THE DRAWINGS

FIG. 1 is a schematic diagram of a configuration of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is a conceptual diagram for explaining an example of a writing operation according to the first embodiment;

FIG. 5 is an illustration showing an example of an irradiation region of multiple beams and a writing target pixel according to the first embodiment;

FIG. 6 is a table showing an example of divided shots of multiple electron beams according to the first embodiment;

FIG. 7 is a conceptual diagram showing the internal configuration of an individual blanking control circuit and a common blanking control circuit according to the first embodiment;

FIG. 8 is a flowchart showing an example of main steps of a writing method according to the first embodiment;

FIG. 9 is an illustration showing an example of assigning a group to a pixel according to the first embodiment;

FIG. 10 is an illustration showing an example of a combination of sub shots for each partial pixel-set irradiation time according to the first embodiment;

FIG. 11 is a table showing an example of an irradiation time of each group of each pixel-set irradiation time according to the first embodiment;

FIG. 12 is an illustration for explaining an example of a multi-beam writing operation according to the first embodiment;

FIG. 13 is an illustration showing an example of a positional relationship between multiple electron beams and a pattern according to the first embodiment;

FIG. 14 is an illustration showing another example of the positional relationship between multiple electron beams and a pattern according to the first embodiment;

FIG. 15 is an illustration showing an example of stripe layers of passes of multiple writing according to a second embodiment;

FIG. 16 is a table showing an example of an assignment of a group to a pixel according to the second embodiment;

FIG. 17 is a table showing another example of an assignment of a group to a pixel according to the second embodiment;

FIG. 18 is an illustration showing an example of a combination of sub shots for each partial pixel-set irradiation time according to a third embodiment;

FIG. 19 is a table showing an example of an irradiation time of each group of each pixel-set irradiation time according to the third embodiment;

FIG. 20 is an illustration showing an example of assigning a group to a pixel according to a fourth embodiment; and

FIG. 21 is an illustration showing an example of assigning a group to a pixel according to a modified example of the fourth embodiment.

### DETAILED DESCRIPTION OF THE INVENTION

Embodiments of the present invention provide a writing method and writing apparatus which can reduce the total amount of ON-beam current simultaneously becoming ON.

Embodiments of the present invention describe multiple electron beams as an example of multiple charged particle beams. The charged particle beam is not limited to the electron beam, and other charged particle beams such as an ion beam may also be used.

### First Embodiment

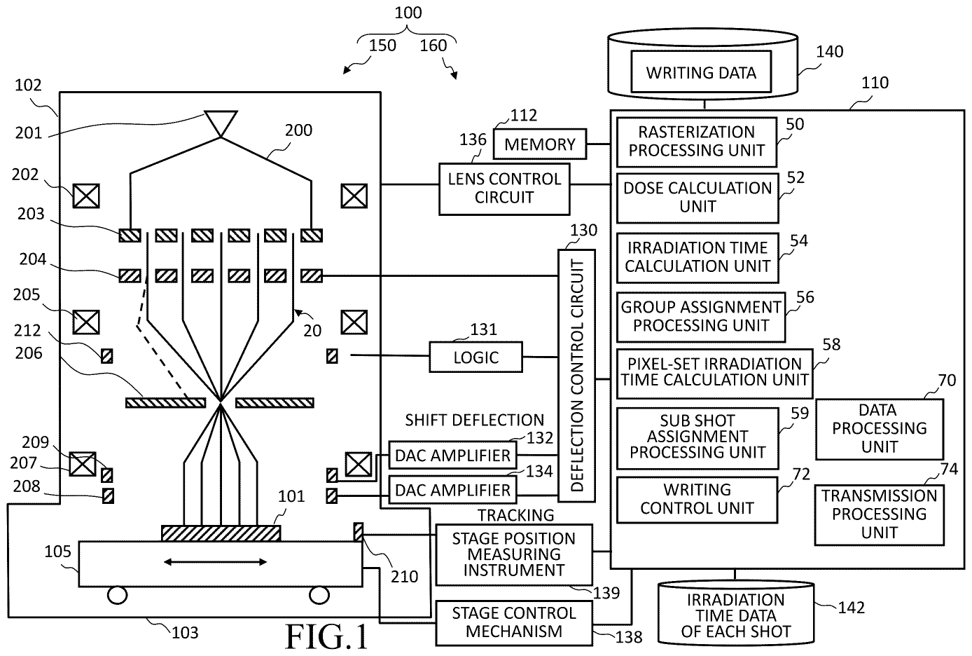

FIG. 1 is a schematic diagram of a configuration of a writing or “drawing” apparatus according to a first embodiment. As shown in FIG. 1, a writing apparatus 100 includes a writing mechanism 150 and a control system circuit 160. The writing apparatus 100 is an example of a multi-charged particle beam writing apparatus and an example of a multi-charged particle beam exposure apparatus. The writing apparatus 100 is an example of a raster beam writing apparatus. The writing mechanism 150 includes an electron optical column 102 (electron beam column) and a writing chamber 103. In the electron optical column 102, there are disposed an electron gun 201, an illumination lens 202, a shaping aperture array substrate 203, a blanking aperture array mechanism 204, a reducing lens 205, a collective deflector 212, a limiting aperture substrate 206, an objective lens 207, a main deflector 208, and a sub deflector 209.

In the writing chamber 103, an XY stage 105 is disposed. On the XY stage 105, there is placed a target object or “sample” 101, such as a mask, serving as a writing target substrate when writing (exposure) is performed. For example, the target object 101 is an exposure mask used in fabricating semiconductor devices, or a semiconductor substrate (silicon wafer) for fabricating semiconductor devices. The target object 101 may be a mask blank on which resist has been applied and nothing has yet been written. On the XY stage 105, a mirror 210 for measuring the position of the XY stage 105 is placed.

The control system circuit 160 includes a control computer 110, a memory 112, a deflection control circuit 130, a logic circuit 131, digital-analog converter (DAC) amplifier units 132 and 134, a lens control circuit 136, a stage control mechanism 138, a stage position measuring instrument 139, and storage devices 140 and 142 such as magnetic disk drives. The control computer 110, the memory 112, the deflection control circuit 130, the logic circuit 131, the lens control circuit 136, the stage control mechanism 138, the stage position measuring instrument 139, and the storage devices 140 and 142 are connected to each other through a bus (not shown). The DAC amplifier units 132 and 134, the logic circuit 131, and the blanking aperture array mechanism 204 are connected to the deflection control circuit 130. The sub deflector 209 is composed of at least four electrodes (or “at least four poles”), and controlled by the deflection control circuit 130 through the DAC amplifier 132 disposed for each electrode. The main deflector 208 is composed of at least four electrodes (or “at least four poles”), and controlled by the deflection control circuit 130 through the DAC amplifier 134 disposed for each electrode. Lenses, such as the illumination lens 202, the reducing lens 205, and the objective lens 207 are controlled by the lens control circuit 136.

The position of the XY stage 105 is controlled by the drive of each axis motor (not shown) which is controlled by the stage control mechanism 138. Based on the principle of laser interferometry, the stage position measurement instrument 139 measures the position of the XY stage 105 by receiving a reflected light from the mirror 210.

In the control computer 110, there are arranged a rasterization processing unit 50, a dose calculation unit 52, an irradiation time calculation unit 54, a group assignment processing unit 56, a pixel-set irradiation time calculation unit 58, a sub shot assignment processing unit 59, a data processing unit 70, a writing control unit 72, and a transmission processing unit 74. Each of the “ . . . units” such as the rasterization processing unit 50, the dose calculation unit 52, the irradiation time calculation unit 54, the group assignment processing unit 56, the pixel-set irradiation time calculation unit 58, the sub shot assignment processing unit 59, the data processing unit 70, the writing control unit 72, and the transmission processing unit 74 includes processing circuitry. The processing circuitry includes, for example, an electric circuit, computer, processor, circuit board, quantum circuit, semiconductor device, or the like. Each “ . . . unit” may use common processing circuitry (the same processing circuitry), or different processing circuitry (separate processing circuitry). Information input/output to/from the rasterization processing unit 50, the dose calculation unit 52, the irradiation time calculation unit 54, the group assignment processing unit 56, the pixel-set irradiation time calculation unit 58, the sub shot assignment processing unit 59, the data processing unit 70, the writing control unit 72, and the transmission processing unit 74, and information being operated are stored in the memory 112 each time.

Writing operations of the writing apparatus 100 are controlled by the writing control unit 72. Processing of transmitting irradiation time data of each shot to the deflection control circuit 130 is controlled by the transmission processing unit 74.

Writing data (chip data) is input from the outside of the writing apparatus 100, and stored in the storage device 140. Chip data defines information on a plurality of figure patterns configuring a chip pattern. Specifically, for each figure pattern, each vertex coordinate is defined in order of forming a figure. Alternatively, for each figure pattern, a figure code, coordinates, a size, and the like are defined, for example.

FIG. 1 shows a configuration necessary for describing the first embodiment. Other configuration elements generally necessary for the writing apparatus 100 may also be included therein.

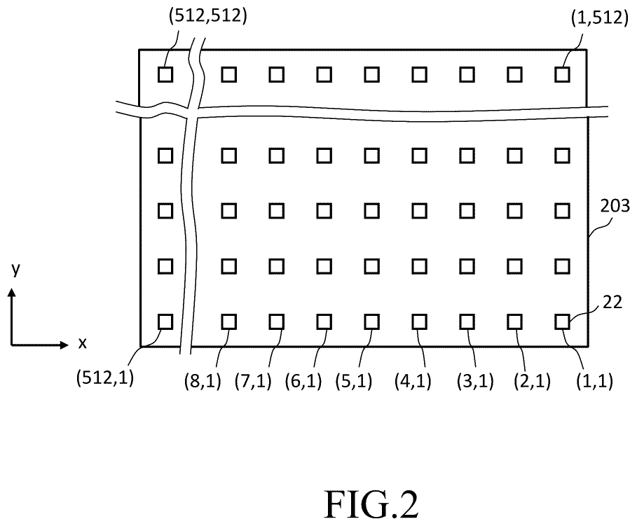

FIG. 2 is a conceptual diagram showing a configuration of a shaping aperture array substrate according to the first embodiment. As shown in FIG. 2, holes (openings) 22 of p columns wide (width in the x direction) and q rows long (length in the y direction) (p≥2, q≥2) are formed, like a matrix, at a predetermined array pitch in the shaping aperture array substrate 203. In the case of FIG. 2, for example, holes 22 of 512×512, that is 512 holes in the x direction and 512 holes in the y direction, are formed. The number of the holes 22 is not limited thereto. For example, it is also preferable to form the holes 22 of 32×32. Each of the holes 22 is a rectangle (including a square) having the same dimension and shape as each other. Alternatively, each of the holes 22 may be a circle with the same diameter as each other. Multiple electron beams 20 are formed by letting portions of an electron beam 200 individually pass through a corresponding one of a plurality of holes 22. In other words, the shaping aperture array substrate 203 forms and emits the multiple electron beams 20. The shaping aperture array substrate 203 serves as an example of an emission source of the multiple electron beams 20 or an example of a multiple beam forming mechanism.

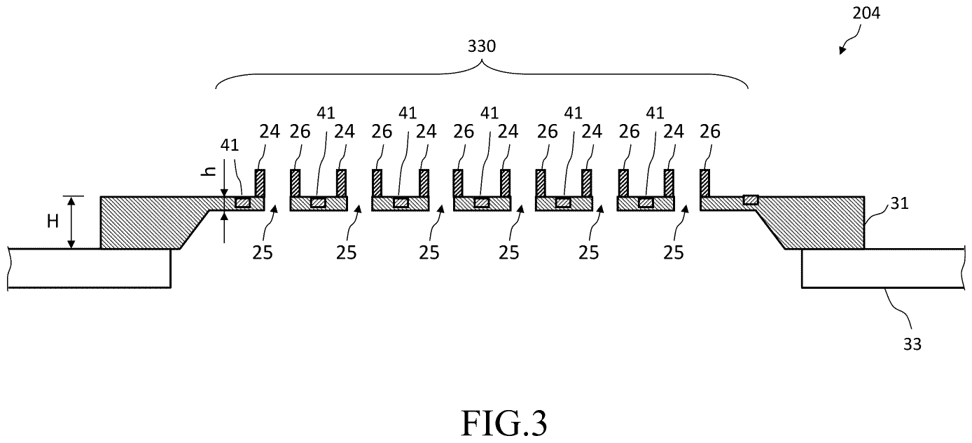

FIG. 3 is a sectional view showing a configuration of a blanking aperture array mechanism according to the first embodiment. In the blanking aperture array mechanism 204, as shown in FIG. 3, a blanking aperture array substrate 31 being a semiconductor substrate made of silicon, etc. is disposed on a support table 33. In a membrane region 330 at the center of the blanking aperture array substrate 31, a plurality of passage holes 25 (openings), through each of which a corresponding one of the multiple electron beams 20 passes, are formed at positions each corresponding to each hole 22 in the shaping aperture array substrate 203 shown in FIG. 2. A pair of a control electrode 24 and a counter electrode 26, (blanker: blanking deflector), is arranged in a manner such that the electrodes 24 and 26 are opposite to each other across a corresponding one of the plurality of the passage holes 25. A control circuit 41 (logic circuit) which applies a deflection voltage to the control electrode 24 for the passage hole 25 concerned is disposed, inside the blanking aperture array substrate 31, close to each corresponding passage hole 25. The counter electrode 26 for each beam is grounded.

In the control circuit 41, an amplifier (not shown) (an example of a switching circuit) is arranged. As an example of the amplifier, a CMOS (Complementary MOS) inverter circuit serving as a switching circuit is disposed. With regard to inputs (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit, which is to be output from the control circuit 41, becomes a positive potential (Vdd), and then, a corresponding beam is deflected by an electric field due to a potential difference from the ground potential of the counter electrode 26, and is controlled to be in a beam-OFF condition by being blocked by the limiting aperture substrate 206. In contrast, in a state (active state) where an H potential is applied to the input (IN) of the CMOS inverter circuit, the output (OUT) of the CMOS inverter circuit, which is to be output from the control circuit 41, becomes a ground potential, and therefore, since there is no potential difference from the ground potential of the counter electrode 26, a corresponding beam is not deflected, and is controlled to be in a beam-ON condition by passing through the limiting aperture substrate 206. Blanking control is provided by such deflection.

Next, operations of the writing mechanism 150 will be described. The electron beam 200 emitted from the electron gun 201 (emission source) almost perpendicularly (for example, vertically) illuminates the whole of the shaping aperture array substrate 203 by the illumination lens 202. A plurality of rectangular holes 22 (openings) are formed in the shaping aperture array substrate 203. The region including all of the plurality of holes 22 is irradiated with the electron beam 200. For example, rectangular multiple beams (a plurality of electron beams) 20 are formed by letting portions of the electron beam 200 applied to the positions of the plurality of holes 22 individually pass through a corresponding one of the plurality of holes 22 in the shaping aperture array substrate 203. The multiple electron beams 20 individually pass through corresponding blankers of the blanking aperture array mechanism 204. The blanker provides blanking control such that a corresponding beam individually passing becomes in an ON condition during the set writing time (irradiation time).

The multiple electron beams 20 having passed through the blanking aperture array mechanism 204 are reduced by the reducing lens 205, and travel toward the hole in the center of the limiting aperture substrate 206. The electron beam which was deflected by the blanker of the blanking aperture array mechanism 204 deviates from the hole in the center of the limiting aperture substrate 206 and is blocked by the limiting aperture substrate 206. In contrast, the electron beam which was not deflected by the blanker of the blanking aperture array mechanism 204 passes through the hole in the center of the limiting aperture substrate 206 as shown in FIG. 1. Thus, the limiting aperture substrate 206 blocks each beam which was deflected to be in an OFF state by the blanker of the blanking aperture array mechanism 204. Then, each beam for one shot of the multiple electron beams 20 is formed by a beam which has been made during a period from becoming beam-ON to becoming beam-OFF and has passed through the limiting aperture substrate 206. The multiple electron beams 20 having passed through the limiting aperture substrate 206 are focused by the objective lens 207 so as to be a pattern image of a desired reduction ratio. Then, all of the multiple electron beams 20 having passed through the limiting aperture substrate 206 are collectively deflected in the same direction by the main deflector 208 and the sub deflector 209 in order to irradiate respective beam irradiation positions on the target object 101. For example, when the XY stage 105 is continuously moving, tracking control is performed by the main deflector 208 so that the beam irradiation position may follow the movement of the XY stage 105. Ideally, the multiple electron beams 20 irradiating at a time are aligned at a pitch obtained by multiplying the array pitch of a plurality of holes 22 in the shaping aperture array substrate 203 by the desired reduction ratio described above.

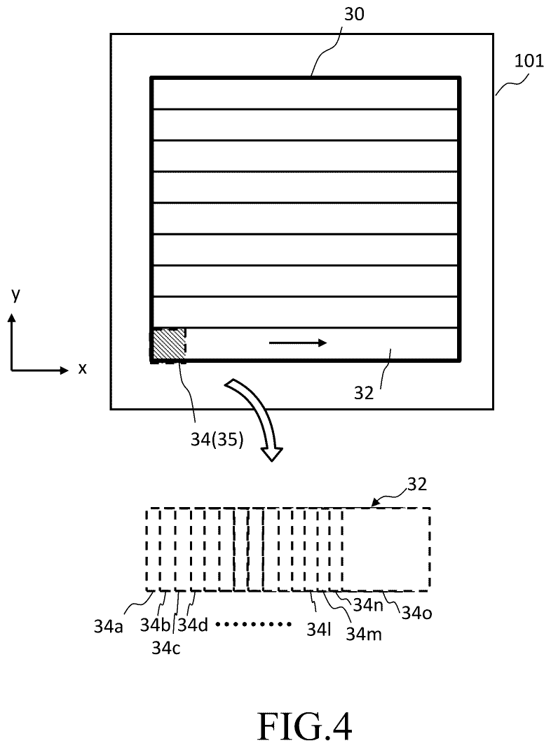

FIG. 4 is a conceptual diagram for explaining an example of a writing operation according to the first embodiment. As shown in FIG. 4, a writing region 30 (bold line) of the target object 101 is virtually divided into a plurality of stripe regions 32 by a predetermined width in the y direction, for example. In the case of FIG. 4, the writing region 30 of the target object 101 is divided in the y direction, for example, into a plurality of stripe regions 32 by the width size being substantially the same as the design size of an irradiation region 34 (writing field) that can be irradiated with one irradiation of the multiple electron beams 20. The x-direction design size of the irradiation region 34 of the multiple electron beams 20 can be defined by (the number of x-direction beams)×(x-direction beam pitch). The y-direction size of the rectangular irradiation region 34 can be defined by (the number of y-direction beams)×(y-direction beam pitch).

First, the XY stage 105 is moved to make an adjustment such that the irradiation region 34 of the multiple electron beams 20 is located at the left end, or at a position further left than the left end, of the first stripe region 32, and then, writing of the first stripe region 32 is performed. When writing the first stripe region 32, the XY stage 105 is moved, for example, in the −x direction, so that the writing may proceed relatively in the x direction. The XY stage 105 is moved, for example, continuously at a constant speed. After writing the first stripe region 32, the stage position is moved in the −y direction by the width of the stripe region 32.

Next, an adjustment is made so that the irradiation region 34 of the multiple electron beams 20 can be located at the left end, or at a position further left than the left end, of the second stripe region 32. Then, writing of the second stripe region 32 is performed by moving the XY stage 105, for example, in the −x direction to proceed the writing relatively in the x direction.

FIG. 4 shows the case where respective stripe regions 32 are written in the same direction, but, it is not limited thereto. For example, with respect to the stripe region 32 to be written following the stripe region 32 having been written in the x direction, it may be written in the −x direction by moving the XY stage 105 in the x direction, for example. Thus, due to indicates to perform writing while alternately changing the writing direction, the stage moving time can be reduced, which results in reducing the writing time. Owing to one shot of multiple beams having been formed by individually passing through the holes 22 in the shaping aperture array substrate 203, a plurality of shot patterns up to the number of the holes 22 are maximally formed at a time.

Although FIG. 4 shows the case where the stage moving for writing each stripe region is performed once for each writing, it is not limited thereto. It is also preferable to perform multiple writing (multiple pass writing) such that the stage moves on the same position a plurality of times. In that case, preferably, the multiple writing is performed while shifting the position in the y direction by 1/n of the width of the stripe region, for example. Alternatively, it is also preferable to perform multiple writing (multiple writing in a pass) that writes the same position plural times by different beams during one stage movement.

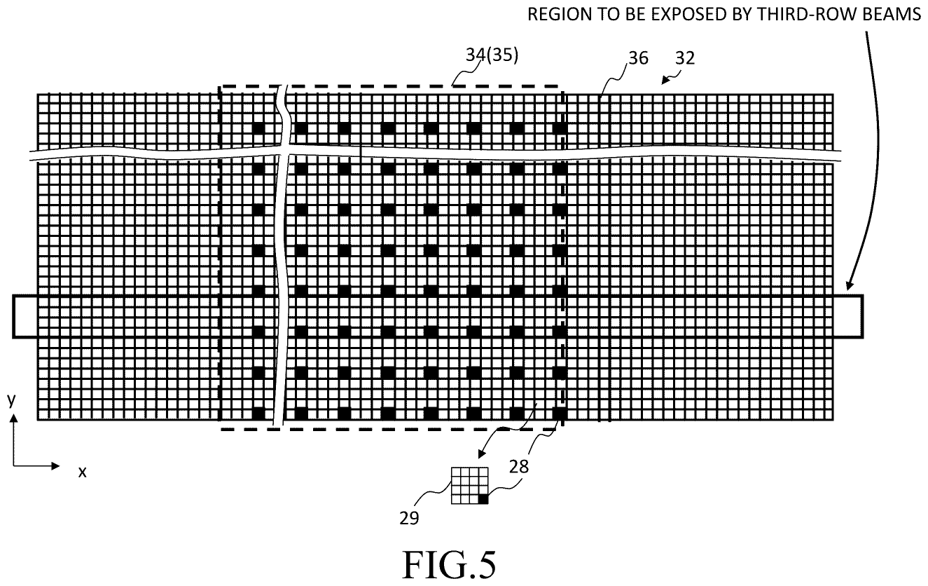

FIG. 5 is an illustration showing an example of an irradiation region of multiple beams and a pixel to be written (writing target pixel) according to the first embodiment. In FIG. 5, the stripe region 32 is divided into a plurality of mesh regions by the beam size of each of the multiple electron beams 20, for example. Each mesh region serves as a writing target pixel 36. The pixel 36 is also referred to as an irradiation unit region. The size of the writing target pixel 36 is not limited to the beam size, and may be any size regardless of beam size. For example, it may be 1/n (n being an integer of 1 or more) of the beam size. FIG. 5 shows the case where the writing region on the target object 101 is divided, for example, in the y direction, into a plurality of stripe regions 32 by the width size being substantially the same as the size of the irradiation region 34 (writing field) that can be irradiated with one irradiation of the multiple electron beams 20. The x-direction size of the rectangular, including square, irradiation region 34 can be defined by (the number of x-direction beams)×(x-direction beam pitch). The y-direction size of the rectangular irradiation region 34 can be defined by (the number of y-direction beams)×(y-direction beam pitch). FIG. 5 shows the case of multiple beams of 512×512 (rows×columns) having been simplified to 8×8 (rows ×columns). In the irradiation region 34, there are shown a plurality of pixels 28 (beam writing positions) which can be irradiated with one shot of the multiple electron beams 20. The pitch between adjacent pixels 28 is the beam pitch (pitch between beams) of the multiple beams. A sub-irradiation region 29 (pitch cell region) is configured by a rectangular, including square, region surrounded by the size of beam pitches in the x and y directions. In the example of FIG. 5, each sub-irradiation region 29 is composed of 4×4 pixels, for example.

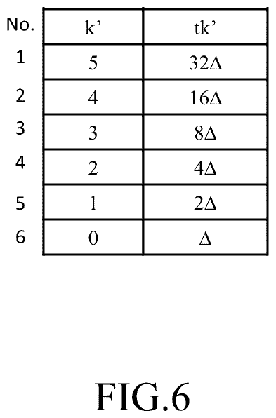

FIG. 6 is a table showing an example of divided shots of multiple electron beams according to the first embodiment. In FIG. 6, the maximum irradiation time Ttr of one shot is divided into a plurality of sub shots (divided shots) having a plurality of sub irradiation time. In other words, the maximum irradiation time Ttr of one shot of the multiple electron beams 20 is divided into n sub shots (divided shots) each having a different sub irradiation time and irradiating the same pixel 36. First, a gray scale value Ntr is defined by dividing the maximum irradiation time Ttr by a quantization unit Δ (gray scale value resolution). For example, when n=6, the maximum irradiation time Ttr is divided into six sub shots. In the case of defining the gray scale value Ntr by n-digit binary numbers, it is preferable to previously set the quantization unit Δ such that the gray scale value Ntr of the maximum irradiation time Ttr is 64. By this, the maximum irradiation time Ttr is 64Δ (Ttr=64Δ). As shown in FIG. 6, each of the n sub shots has one of the irradiation time of 2^{k}′Δ where the digit number k′ is one of θ to 5 (k′=0 to k′=5). In other words, it has the sub irradiation time of one of 32Δ(=2⁵Δ), 16Δ(=2⁴Δ), 8Δ(=2³Δ), 4Δ(=2²Δ), 2Δ(=2¹Δ), and Δ(=2^{θ}Δ). That is, one shot of multiple beams is divided into a sub shot with the sub irradiation time tk′ of 32Δ, a sub shot with the sub irradiation time tk′ of 16Δ, a sub shot with the sub irradiation time tk′ of 8Δ, a sub shot with the sub irradiation time tk′ of 4Δ, a sub shot with the sub irradiation time tk′ of 2Δ, and a sub shot with the sub irradiation time tk′ of Δ. n sub shots are continuously performed during one shot period. The n sub shots applied during one shot period are performed by the same beams for each pixel 36.

The maximum irradiation time Ttr is equivalent to the irradiation time of the pixel whose dose is the largest in all the pixels 36 in the writing region 30 of the target object 101. That is, the maximum irradiation time Ttr is equivalent to the irradiation time whose dose is the largest. In the writing apparatus 100, the constant speed of the stage is based on a shot cycle obtained by adding the settling time to the maximum irradiation time Ttr.

Therefore, any irradiation time t(=NΔ) for irradiating each pixel 36 can be defined by a total of sub irradiation time of a set of at least one sub shot, as long as whose irradiation time is not zero, based on a plurality of sub shots each having one of a plurality of sub irradiation time defined by 32Δ(=2⁵Δ), 16Δ(=2⁴Δ), 8Δ(=2³Δ), 4Δ(=2²Δ), 2Δ(=2¹Δ), and Δ(=2^{θ}Δ).

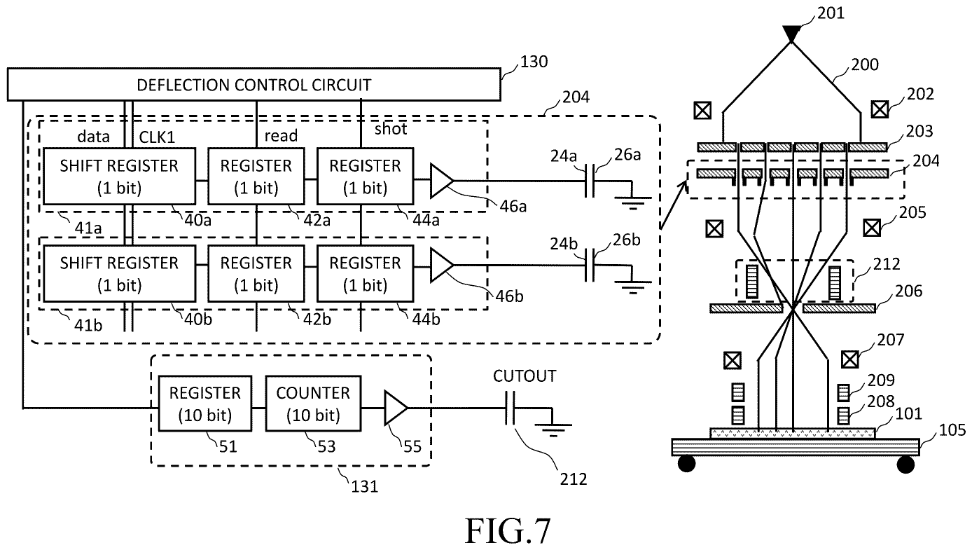

FIG. 7 is a conceptual diagram showing the internal configuration of an individual blanking control circuit and a common blanking control circuit according to the first embodiment. As shown in FIG. 7, in each control circuit 41 for individual blanking control placed in the blanking aperture array mechanism 204 inside the body of the writing apparatus 100, there are arranged a shift register 40, a register 42, a register 44, and an amplifier 46. Individual blanking control for each beam is performed by a 1-bit control signal, for example. That is, for example, a 1-bit control signal is input/output to/from the shift register 40, the registers 42 and 44, and the amplifier 46. Since the amount of information of the control signal is small, the installation area of the control circuit can be made small. In other words, even when the control circuit is placed in the blanking aperture array mechanism 204 whose installation space is small, more beams can be arranged at a smaller beam pitch. This increases the amount of current passing through the blanking plate, and therefore, improves the writing throughput.

Furthermore, in the logic circuit 131 for common blanking, there are arranged a register 51, a counter 53, and an amplifier 55. Since, unlike the amplifier 46, these do not independently perform controlling for each beam, it is sufficient to use one circuit which commonly performs ON/OFF control of all the beams. Accordingly, even when a circuit for a high speed response is arranged, no problem occurs with respect to restriction on the installation space and the current to be used in the circuit. Therefore, the amplifier 55 operates at a very high speed compared to the amplifier 46 that can be implemented in the blanking aperture array mechanism 204. The amplifier 55 is controlled by a 10-bit control signal, for example. That is, for example, a 10-bit control signal is input/output to/from the register 51 and the counter 53.

According to the first embodiment, blanking control of each beam is performed by using both the beam ON/OFF control by each control circuit 41 for individual blanking control described above and the beam ON/OFF control by the logic circuit 131 for common blanking control that collectively performs blanking control of all the multiple beams.

The shift registers 40 in the control circuits 41 for beams in the same row, for example, in p×q multiple beams are connected in series. For example, irradiation time data (ON/OFF control signal) of sub shots of beams in the same row in p×q multiple beams are transmitted in series. Then, for example, the transmitted irradiation time data of each beam is stored in a corresponding shift register 40 by p-times clock signals.

Then, responsive to input of a read signal from the deflection control circuit 130, the individual register 42 reads and stores an ON/OFF signal, based on the stored k-th sub shot data (1 bit). Furthermore, irradiation time data (10 bits) of the k-th sub shot is transmitted from the deflection control circuit 130, and stored in the register 51 for common blanking control.

Next, an individual shot signal of the k-th sub shot is output from the deflection control circuit 130 to the individual registers 44 of all of the beams. Thereby, the individual register 44 for each beam maintains data stored in the individual register 42 only during the time of the ON condition of the individual shot signal, and outputs a beam ON signal or a beam OFF signal to the individual amplifier 46 in accordance with a maintained ON/OFF signal. Instead of the individual shot signal, a load signal for keeping loading and a reset signal for resetting stored information may be output to the individual register 44. The individual amplifier 46 applies a beam ON voltage or a beam OFF voltage to the control electrode 24 in accordance with an input beam ON signal or beam OFF signal. On the other hand, after the individual shot signal, a common shot signal of the k-th sub shot is output from the deflection control circuit 130 to the counter 53 for common blanking control. The counter 53 performs counting only during the time indicated by the ON/OFF control signal stored in the register 51, and, during this period, outputs a beam ON signal to the common amplifier 55. The common amplifier 55 applies a beam ON voltage to the deflector 212 only during the time of inputting a beam ON signal from the counter 53.

For example, compared with ON/OFF switching of the individual blanking mechanism 47, the common blanking mechanism performs switching from OFF to ON after a voltage stabilization time (settling time) S1/S2 of the amplifier 46 has passed. After the individual amplifier has become ON and the settling time S1 of the individual amplifier 46 at switching from OFF to ON has passed, the common amplifier 55 becomes ON. Thereby, beam irradiation at an unstable voltage at the time of rise of the individual amplifier 46 can be avoided. Then, the common amplifier 55 becomes OFF after the irradiation time of the target k-th sub shot has passed. Consequently, in the case of both the individual amplifier 46 and the common amplifier 55 being in the ON condition, an actual beam becomes ON to irradiate the target object 101. Therefore, preferably, it is controlled such that the ON time period of the common amplifier 55 is the sub irradiation time of the actual beam. In contrast, in the case of the common amplifier 55 becoming ON when the individual amplifier 46 is OFF, preferably, after the individual amplifier 46 becomes OFF and the settling time S2 of the individual amplifier 46 at switching from ON to OFF has passed, the common amplifier 55 becomes ON. Thereby, beam irradiation at an unstable voltage at the fall time of the individual amplifier 46 can be avoided.

In recent electron beam writing, there is a tendency to reduce the pixel size in order to increase resolution of small patterns. Along with miniaturization of the pixel size, pixels (pixel 36) whose pattern area density (coverage) is 100% become dominant in the region where a figure pattern is arranged. That is, the smaller the pixel compared with a pattern dimension becomes, the lower the ratio of a pixel lying on (overlapping with) the edge of a pattern to the whole pixels included in the pattern region becomes. In the region where no figure pattern is arranged, the pattern area density (coverage) of the pixel 36 is 0%. Therefore, there are many cases in which the dose of each of adjacent pixels is the same as each other.

Then, according to the first embodiment, pixels 36 to be in the same pixel-set are determined in advance, and one of a plurality of groups A and B is assigned to each pixel 36 such that each pixel 36 in the same pixel-set is assigned a different group, and a plurality of pixels 28 irradiated with each shot of the multiple electron beams 20 are assigned groups composed of different groups. It is specifically described below.

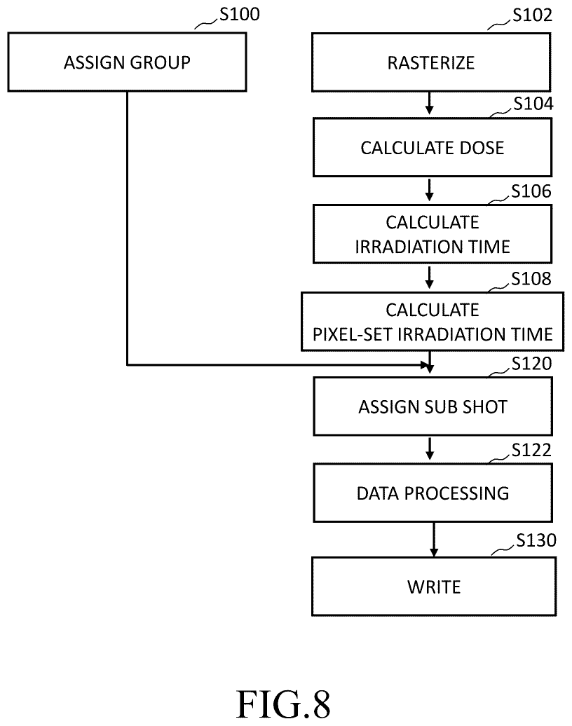

FIG. 8 is a flowchart showing an example of main steps of a writing method according to the first embodiment. In FIG. 8, the writing method of the first embodiment executes a series of steps: a group assignment step (S100), a rasterization processing step (S102), a dose calculation step (S104), an irradiation time calculation step (S106), a pixel-set irradiation time calculation step (S108), a sub shot assignment step (S120), a data processing step (S122), and a writing step (S130).

In the group assignment step (S100), the group assignment processing unit 56 assigns one of a plurality of groups to each of a plurality of pixels 36 (irradiation unit regions) which are unit regions, obtained by dividing the stripe region 32 (an example of a writing region) of the target object 101, to be irradiated with each beam of the multiple electron beams 20, and for which a plurality of pixel-sets each composed of two or more pixels 36 are set in advance, such that each pixel 36 in the same pixel-set belongs to a group different from each other, and a plurality of pixels 36 irradiated with each shot of the multiple electron beams 20 include pixels 36 of different groups. In other words, the group assignment processing unit 56 assigns one group of a plurality of groups to each pixel 36 of a plurality of pixels 36 being irradiation unit regions which are obtained by dividing the stripe region 32 (an example of a writing region) of the target object 101, and each of which is irradiated with each beam of the multiple electron beams 20, such that each of pixels 36 determined in advance to be in the same pixel-set belongs to a different group and that a plurality of pixels 36 irradiated with each shot of the multiple electron beams 20 are composed of pixels 36 of different groups.

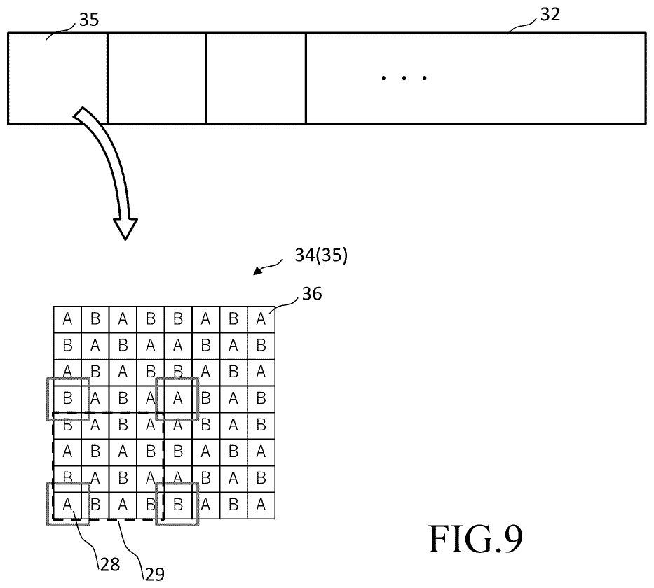

FIG. 9 is an illustration showing an example of assigning a group to a pixel according to the first embodiment. In FIG. 9, first, each stripe region 32 of the target object 101 is divided into a plurality of rectangular regions 35 of the same size as the irradiation region 34 of the multiple electron beams 20. FIG. 9 shows the case of 2×2 multiple electron beams 20, for example, and four pixels 36 are arranged in a pitch between beams, for example. In that case, the rectangular region 35 being the same size as the irradiation region 34 is composed of 8×8 pixels, for example. FIG. 9 shows the case where a pixel-set is composed of adjacent pixels. Specifically, a pixel-set is composed of two pixels adjacent to each other in the x direction in the same sub-irradiation region 29 (beam pitch region). Then, in each pixel-set, adjacent pixels 36 are individually assigned one of a plurality of groups A and B such that each of the adjacent pixels 36 belongs to a different group. In that case, the plurality of groups are assigned to be alternate each other in both the x and y directions.

Group assignment is performed such that a plurality of pixels 28 irradiated with each shot of the multiple electron beams 20 include those of different groups. FIG. 9 shows the case where group assignment is performed such that beams adjacent in the x and y directions of 2×2 multiple electron beams 20 irradiate the pixels 28 of different groups. If a pixel shifted in position from the pixel concerned by one beam pitch in the x or y direction belongs to a different group, it is preferable because, in all the shots, a half of multiple beams exposes pixels in the group A, the other half exposes pixels in the group B, and beams individually expose the group A or B are uniformly distributed in multiple beam arrays.

In addition, although pixels of the same group are aligned at the border of the sub-irradiation region 29, it is acceptable because those pixels belong to different pixel-sets.

In the rasterization processing step (S102), the rasterization processing unit 50 reads chip pattern data (writing data) from the storage device 140, and performs rasterization processing. Specifically, for each pixel 36, pattern density ρ(x) (pattern area density) of a figure pattern arranged in the pixel concerned is calculated. For example, it is preferable to perform rasterization processing for each stripe region 32.

In the dose calculation step (S104), the dose calculation unit 52 calculates, for each pixel 36, a dose to be incident on the pixel 36 concerned. Specifically, it operates as follows: For example, the dose D can be calculated by multiplying a preset base dose D_{base}, a proximity effect correction dose Dₚ, and a pattern density ρ. The proximity effect correction dose Dₚ is obtained as a relative value standardized by defining the base dose D_{base} to be 1. Thus, it is preferable to obtain the dose D to be in proportion to a pattern area density calculated for each pixel 36. With respect to the proximity effect correction dose Dₚ, the writing region (for example, in this case, the stripe region 32) is virtually divided into a plurality of proximity mesh regions (mesh regions for proximity effect correction calculation) by a predetermined size. The size of the proximity mesh region is preferably set to be about 1/10 of the influence range of the proximity effect, such as about 1 μm. Then, writing data is read from the storage device 140, and, for each proximity mesh region, a pattern density ρ′ (pattern area density) of a pattern arranged in the proximity mesh region concerned is calculated.

Next, a proximity effect correction dose Dₚ for correcting a proximity effect is calculated for each proximity mesh region. Here, the size of the mesh region to calculate the proximity effect correction dose Dₚ does not need to be the same as that of the mesh region to calculate a pattern density ρ.

Furthermore, a correction model of the proximity effect correction dose Dₚ and its calculation method may be the same as those used in the conventional single beam writing system. A dose map which defines dose data for each pixel 36 is generated.

In the case of indicates to perform multiple writing, a dose map is generated for each writing processing of each time of multiple writing. In other words, a dose map is generated for each stripe layer. The generated dose map is stored in the storage device 142.

In the irradiation time calculation step (S106), the irradiation time calculation unit 54 calculates, for each pixel 36, an irradiation time “t” of an electron beam for applying a calculated dose D to the pixel 36 concerned. The irradiation time “t” can be obtained by dividing the dose D by a current density J. The irradiation time is calculated as an integer value which can be used in the counter 53. For example, it is calculated as an integer of 10 bits. Hereafter, it is supposed that a 6-bit integer is calculated. Thereby, an irradiation time map defining irradiation time data for each pixel 36 is generated. The generated irradiation time map is stored in the storage device 142.

In the pixel-set irradiation time calculation step (S108), the pixel-set irradiation time calculation unit 58 calculates, for each pixel-set, a pixel-set irradiation time (nominal pixel-set irradiation time). Preferably, an average irradiation time (average value) of the irradiation time which is set for each pixel 36 in the pixel-set concerned is used as a pixel-set irradiation time, for example. The pixel-set irradiation time obtained here is not limited to an average value, and it may be a median value or other representative values, such as a minimum or maximum value. Here, the pixel-set irradiation time calculation unit 58 calculates, for each pixel-set, an average irradiation time of the irradiation time of pixels in a pixel-set, as the pixel-set irradiation time, for example. As described above, along with miniaturization of the pixel size, the number of pixels whose respective pattern area densities are 100% increases. For example, if pixels adjacent to each other in a figure pattern are in the same pixel-set, the irradiation time of each of both the pixels 36 is the same value in many cases. In that case, for example, the average irradiation time, serving as a pixel-set irradiation time, becomes coincident with the irradiation time defined for each pixel 36. If pixels adjacent to each other across the edge of a figure pattern are in the same pixel-set, the irradiation time of both the pixels 36 are different from each other. In that case, for example, the average irradiation time, serving as a pixel-set irradiation time, is not coincident with the irradiation time defined for each pixel 36. The dose of a pixel across the edge greatly affects the edge position of a pattern to be formed by writing. Then, a threshold is set for the difference between doses (irradiation time) of pixels in the same pixel-set. If the difference between doses (irradiation time) of pixels in the same pixel-set is larger than the threshold, the pixel-set irradiation time calculation step (S108) is skipped, and the irradiation time calculated in the irradiation time calculation step (S106) may be used as it is.

In the sub shot assignment step (S120), the sub shot assignment processing unit 59 assigns, to the pixels 36 each assigned one group of a plurality of groups, at least one sub shot each preset according to the irradiation time having been set for the pixel 36 concerned or a value calculated based on the irradiation time, in a plurality of sub shots each having one of a plurality of sub irradiation time obtained by dividing the maximum irradiation time of one shot, and assigns, to the pixels 36 each assigned another group of the plurality of groups, at least one sub shot including a sub shot other than the at least one sub shot having been preset for the one group in the same pixel-set. In other words, the sub shot assignment processing unit 59 assigns, to the pixels 36 each assigned one group (e.g., group B) of a plurality of groups A and B, at least one sub shot (fixed bit string) being set in advance according to the pixel-set irradiation time (an example of the irradiation time, or of a value based on the irradiation time) which is set for the pixel 36 concerned in a plurality of sub shots in the case of n=6, for example. Then, the sub shot assignment processing unit 59 assigns, to the pixels 36 each assigned another group (e.g., group A) in the plurality of groups A and B, at least one sub shot including the one other than the at least one sub shot which has been set in advance for the one group (e.g., group B) in the same pixel-set.

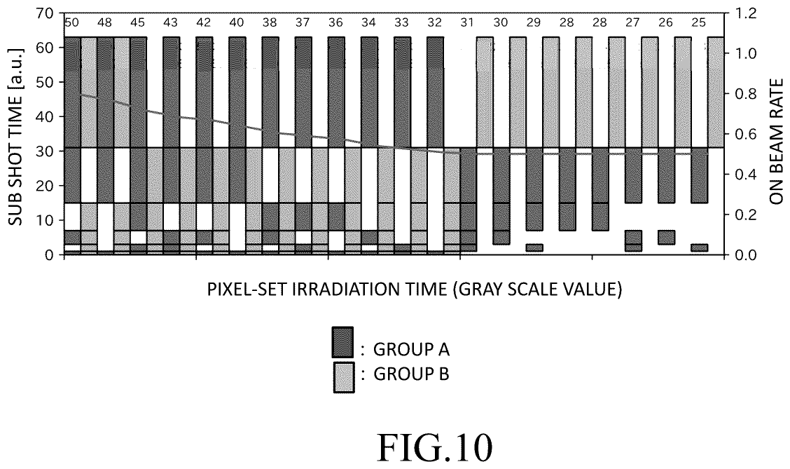

FIG. 10 is an illustration showing an example of a combination of sub shots for each partial pixel-set irradiation time according to the first embodiment.

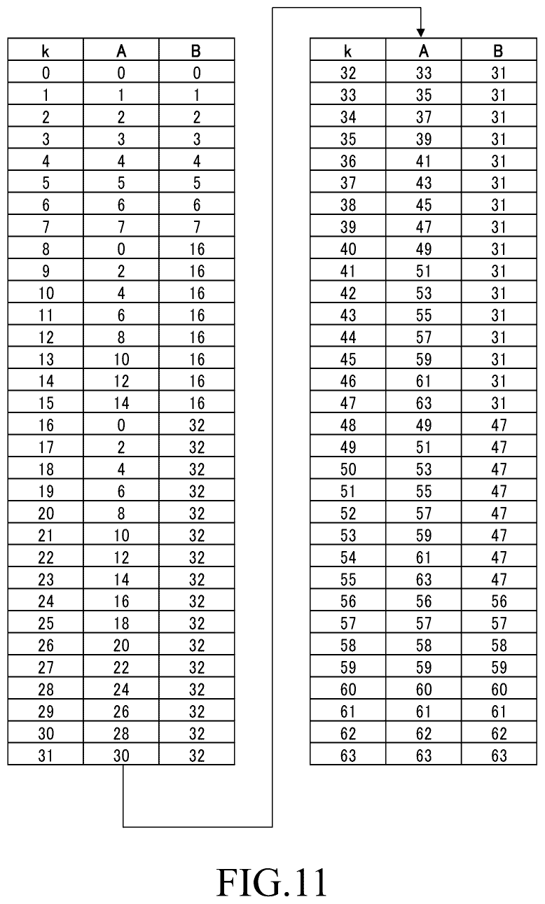

FIG. 11 is a table showing an example of an irradiation time of each group of each pixel-set irradiation time according to the first embodiment.

In FIG. 10, the ordinate axis represents a sub shot time (sub irradiation time of a sub shot), and the abscissa axis represents a pixel-set irradiation time (gray scale value)). FIG. 11 shows a combination of irradiation time of the groups A and B for each gray scale value, from k=0 to k=63, of each pixel-set irradiation time. FIG. 10 shows an example of a combination of sub shots assigned to each group, from k=25 to k=50, in the gray scale values from k=0 to k=63.

According to the first embodiment, with respect to each pixel-set, in order that a value calculated based on the total of sub irradiation time of a preset at least one sub shot assigned to one group, and the total of sub irradiation time of at least one sub shot assigned to another group may become a pixel-set irradiation time which is set for each pixel 36 in the pixel-set concerned, the assignment to the another group by the at least one sub shot is performed. In other words, according to the first embodiment, for each pixel-set, in order that the average between the total of sub irradiation time of at least one preset sub shot assigned to one group (e.g., group B) and the total of sub irradiation time of at least one sub shot assigned to another group (e.g., group A) may become the pixel-set irradiation time set for each pixel 36 in the pixel-set concerned, the assignment to the another group (e.g., group A) by at least one sub shot is performed.

In the example of FIG. 10, with respect to pixels in each of the pixel-sets of the pixel-set irradiation time defined by gray scale values from k=25 to k=31, a preset sub shot of 32Δ is assigned to the pixels 36 of the group B. To the pixel 36 of the group A, a combination of at least one sub shot including at least one sub shot other than the sub shot of 32Δ assigned to the pixel of the group B is assigned.

For example, as shown in FIG. 11, with respect to the pixel-set irradiation time of k=25, since the sub shot of 32Δ is preset for the group B, at least one sub shot whose total is 18Δ is assigned to the group A so that the average may become 25Δ. In the case of FIG. 10, the sub shot of 16Δ and the sub shot of 2Δ are assigned.

For example, as shown in FIG. 11, with respect to the pixel-set irradiation time of k=26, since the sub shot of 32Δ is preset for the group B, at least one sub shot whose total is 20Δ is assigned to the group A so that the average may become 26Δ. In the case of FIG. 10, the sub shot of 16Δ and the sub shot of 4Δ are assigned.

For example, as shown in FIG. 11, with respect to the pixel-set irradiation time of k=27, since the sub shot of 32Δ is preset for the group B, at least one sub shot whose total is 22Δ is assigned to the group A so that the average may become 27Δ. In the case of FIG. 10, the sub shot of 16Δ, the sub shot of 4Δ, and the sub shot of 2Δ are assigned.

For example, as shown in FIG. 11, with respect to the pixel-set irradiation time of k=28, since the sub shot of 32Δ is preset for the group B, at least one sub shot whose total is 24Δ is assigned to the group A so that the average may become 28Δ. In the case of FIG. 10, the sub shot of 16Δ and the sub shot of 8Δ are assigned.

For example, as shown in FIG. 11, with respect to the pixel-set irradiation time of k=29, since the sub shot of 32Δ is preset for the group B, at least one sub shot whose total is 26Δ is assigned to the group A so that the average may become 29Δ. In the case of FIG. 10, the sub shot of 16Δ, the sub shot of 8Δ, and the sub shot of 2Δ are assigned.

For example, as shown in FIG. 11, with respect to the pixel-set irradiation time of k=30, since the sub shot of 32Δ is preset for the group B, at least one sub shot whose total is 28Δ is assigned to the group A so that the average may become 30Δ. In the case of FIG. 10, the sub shot of 16Δ, the sub shot of 8Δ, and the sub shot of 4Δ are assigned.

For example, as shown in FIG. 11, with respect to the pixel-set irradiation time of k=31, since the sub shot of 32Δ is preset for the group B, at least one sub shot whose total is 30Δ is assigned to the group A so that the average may become 31Δ. In the case of FIG. 10, the sub shot of 16Δ, the sub shot of 8Δ, the sub shot of 4Δ, and the sub shot of 2Δ are assigned.

In the example of FIG. 10, with respect to pixels in each of the pixel-sets of the pixel-set irradiation time defined by gray scale values from k=32 to k=47, the sub shot of 16Δ, the sub shot of 8Δ, the sub shot of 4Δ, the sub shot of 2Δ, and the sub shot of 1Δ are assigned, as preset sub shots, to the pixel 36 of the group B. To the pixel 36 of the group A, a combination of at least one sub shot including at least one sub shot other than the sub shot of 16Δ, the sub shot of 8Δ, the sub shot of 4Δ, the sub shot of 2Δ, and the sub shot of 1Δ assigned to the pixel of the group B is assigned.

For example, as shown in FIG. 11, with respect to the pixel-set irradiation time of k=32, since the sub shot of 16Δ, the sub shot of 8Δ, the sub shot of 4Δ, the sub shot of 2Δ, and the sub shot of 1Δ, whose total is 31Δ, are preset for the group B, at least one sub shot whose total is 33Δ is assigned to the group A so that the average may become 32Δ. In the case of FIG. 10, the sub shot of 32Δ, and the sub shot of 1Δ are assigned.

For example, as shown in FIG. 11, with respect to the pixel-set irradiation time of k=33, since the sub shot of 16Δ, the sub shot of 8Δ, the sub shot of 4Δ, the sub shot of 2Δ, and the sub shot of 1Δ, whose total is 31Δ, are preset for the group B, at least one sub shot whose total is 35Δ is assigned to the group A so that the average may become 33Δ. In the case of FIG. 10, the sub shot of 32Δ, and the sub shot of 2Δ are assigned.

For example, as shown in FIG. 11, with respect to the pixel-set irradiation time of k=34, since the sub shot of 16Δ, the sub shot of 8Δ, the sub shot of 4Δ, the sub shot of 2Δ, and the sub shot of 1Δ, whose total is 31Δ, are preset for the group B, at least one sub shot whose total is 37Δ is assigned to the group A so that the average may become 34Δ. In the case of FIG. 10, the sub shot of 32Δ, the sub shot of 4Δ, and the sub shot of 1Δ are assigned.

For example, as shown in FIG. 11, with respect to the pixel-set irradiation time of k=36, since the sub shot of 16Δ, the sub shot of 8Δ, the sub shot of 4Δ, the sub shot of 2Δ, and the sub shot of 1Δ, whose total is 31Δ, are preset for the group B, at least one sub shot whose total is 41Δ is assigned to the group A so that the average may become 36Δ. In the case of FIG. 10, the sub shot of 32Δ, the sub shot of 8Δ, and the sub shot 1Δ are assigned.

For example, as shown in FIG. 11, with respect to the pixel-set irradiation time of k=37, since the sub shot of 16Δ, the sub shot of 8Δ, the sub shot of 4Δ, the sub shot of 2Δ, and the sub shot of 1Δ, whose total is 31Δ, are preset for the group B, at least one sub shot whose total is 43Δ is assigned to the group A so that the average may become 37Δ. In the case of FIG. 10, the sub shot of 32Δ, the sub shot of 8Δ, the sub shot of 2Δ, and the sub shot of 1Δ are assigned.

For example, as shown in FIG. 11, with respect to the pixel-set irradiation time of k=38, since the sub shot of 16Δ, the sub shot of 8Δ, the sub shot of 4Δ, the sub shot of 2Δ, and the sub shot of 1Δ, whose total is 31Δ, are preset for the group B, at least one sub shot whose total is 45Δ is assigned to the group A so that the average may become 38Δ. In the case of FIG. 10, the sub shot of 32Δ, the sub shot of 8Δ, the sub shot of 4Δ, and the sub shot of 1Δ are assigned.

For example, as shown in FIG. 11, with respect to the pixel-set irradiation time of k=40, since the sub shot of 16Δ, the sub shot of 8Δ, the sub shot of 4Δ, the sub shot of 2Δ, and the sub shot of 1Δ, whose total is 31Δ, are preset for the group B, at least one sub shot whose total is 49Δ is assigned to the group A so that the average may become 40Δ. In the case of FIG. 10, the sub shot of 32Δ, the sub shot of 16Δ, and the sub shot of 1Δ are assigned.

For example, as shown in FIG. 11, with respect to the pixel-set irradiation time of k=42, since the sub shot of 16Δ, the sub shot of 8Δ, the sub shot of 4Δ, the sub shot of 2Δ, and the sub shot of 1Δ, whose total is 31Δ, are preset for the group B, at least one sub shot whose total is 53Δ is assigned to the group A so that the average may become 42Δ. In the case of FIG. 10, the sub shot of 32Δ, the sub shot of 16Δ, the sub shot of 4Δ, and the sub shot of 1Δ are assigned.

For example, as shown in FIG. 11, with respect to the pixel-set irradiation time of k=45, since the sub shot of 16Δ, the sub shot of 8Δ, the sub shot of 4Δ, the sub shot of 2Δ, and the sub shot of 1Δ, whose total is 31Δ, are preset for the group B, at least one sub shot whose total is 59Δ is assigned to the group A so that the average may become 45Δ. In the case of FIG. 10, the sub shot of 32Δ, the sub shot of 16Δ, the sub shot of 8Δ, the sub shot of 4Δ, and the sub shot of 1Δ are assigned.

In the example of FIG. 10, with respect to pixels in each of the pixel-sets of the pixel-set irradiation time defined by gray scale values from k=48 to k=50, the sub shot of 32Δ, the sub shot of 8Δ, the sub shot of 4Δ, the sub shot of 2Δ, and the sub shot of 1Δ are assigned, as preset sub shots, to the pixel 36 of the group B. To the pixel 36 of the group A, a combination of at least one sub shot including at least one sub shot other than the sub shot of 32Δ, the sub shot of 8Δ, the sub shot of 4Δ, the sub shot of 2Δ, and the sub shot of 1Δ assigned to the pixels of the group B is assigned.

For example, as shown in FIG. 11, with respect to the pixel-set irradiation time of k=48, since the sub shot of 32Δ, the sub shot of 8Δ, the sub shot of 4Δ, the sub shot of 2Δ, and the sub shot of 1Δ, whose total is 47Δ, are preset for the group B, at least one sub shot whose total is 49Δ is assigned to the group A so that the average may become 48Δ. In the case of FIG. 10, the sub shot of 32Δ, the sub shot of 16Δ, and the sub shot of 1Δ are assigned.

For example, as shown in FIG. 11, with respect to the pixel-set irradiation time of k=50, since the sub shot of 32Δ, the sub shot of 8Δ, the sub shot of 4Δ, the sub shot of 2Δ, and the sub shot of 1Δ, whose total is 47Δ, are preset for the group B, at least one sub shot whose total is 53Δ is assigned to the group A so that the average may become 50Δ. In the case of FIG. 10, the sub shot of 32Δ, the sub shot of 16Δ, the sub shot of 4Δ, and the sub shot of 1Δ are assigned.

According to the example of FIG. 11, when k=0, the irradiation time is zero. When k=1, the sub shot of 1Δ is preset for the group B. When k=2, the sub shot of 2Δ is preset for the group B. When k=3, the sub shot of 2Δ and the sub shot of 1Δ are preset for the group B. When k=4, the sub shot of 4Δ is preset for the group B. When k=5, the sub shot of 4Δ and the sub shot of 1Δ are preset for the group B. When k=6, the sub shot of 4Δ and the sub shot of 2Δ are preset for the group B. When k=7, the sub shot of 4Δ, the sub shot of 2Δ, and the sub shot of 1Δ are preset for the group B.

When k=8 to k=15, the sub shot of 16Δ is preset for the group B. When k=16 to k=31, the sub shot of 32Δ is preset for the group B.

When k=32 to k=47, the sub shot of 16Δ, the sub shot of 8Δ, the sub shot of 4Δ, the sub shot of 2Δ, and the sub shot of 1Δ are preset for the group B.

When k=48 to k=55, the sub shot of 32Δ, the sub shot of 8Δ, the sub shot of 4Δ, the sub shot of 2Δ, and the sub shot of 1Δ are preset for the group B.

When k=56, the sub shot of 32Δ, the sub shot of 16Δ, and the sub shot of 8Δ are preset for the group B. When k=57, the sub shot of 32Δ, the sub shot of 16Δ, the sub shot of 8Δ, and the sub shot of 1Δ are preset for the group B. When k=58, the sub shot of 32Δ, the sub shot of 16Δ, the sub shot of 8Δ, and the sub shot of 2Δ are preset for the group B. When k=59, the sub shot of 32Δ, the sub shot of 16Δ, the sub shot of 8Δ, the sub shot of 2Δ, and the sub shot of 1Δ are preset for the group B. When k=60, the sub shot of 32Δ, the sub shot of 16Δ, the sub shot of 8Δ, and the sub shot of 4Δ are preset for the group B. When k=61, the sub shot of 32Δ, the sub shot of 16Δ, the sub shot of 8Δ, the sub shot of 4Δ, and the sub shot of 1Δ are preset for the group B. When k=62, the sub shot of 32Δ, the sub shot of 16Δ, the sub shot of 8Δ, the sub shot of 4Δ, and the sub shot of 2Δ are preset for the group B. When k=63, the sub shot of 32Δ, the sub shot of 16Δ, the sub shot of 8Δ, the sub shot of 4Δ, the sub shot of 2Δ, and the sub shot of 1Δ are preset for the group B.

Irradiation time data indicating a combination of sub shots can be defined by 6-bit data if the number(=n) of divided shots is n=6. For example, if the data is 100000, it indicates to perform a sub shot of 32Δ (k'=5 ). For example, if the data is 010000, it indicates to perform a sub shot of 16Δ (k′=4 ). For example, if the data is 001000, it indicates to perform a sub shot of 8Δ (k′=3 ). For example, if the data is 000100, it indicates to perform a sub shot of 4Δ (k′=2 ). For example, if the data is 000010, it indicates to perform a sub shot of 2Δ (k′=1 ). For example, if the data is 000001, it indicates to perform a sub shot of 1Δ (k′=0 ). Each bit value indicates one sub shot. Thus, for example, 111111 indicates to perform a sub shot of 32Δ, a sub shot of 16Δ, a sub shot of 8Δ, a sub shot of 4Δ, a sub shot of 2Δ, and a sub shot of 1Δ. If the data is 000000, it indicates zero irradiation time.

As described above, it is intended not to use the sub shot of the same sub irradiation time for the group A and the group B as much as possible. By this, the number of beams which simultaneously become ON during one shot can be reduced. Therefore, the average beam current during one shot cycle can be reduced.

In the data processing step (S122), the data processing unit 70 performs data processing to rearrange the irradiation time data indicating a combination of sub shots, in the order of shots. The irradiation time data is stored in the storage device 142.

Then, the transmission processing unit 74 transmits the irradiation time data to the deflection control circuit 130 in the order of shots.

In the writing step (S130), under the control of the writing control unit 72, using the multiple electron beams 20, the writing mechanism 150 writes a pattern on the target object 101 by performing, for each shot, a sub shot assigned to each pixel 36 to be irradiated with the multiple electron beams 20. Such a sub shot may be performed only when corresponding irradiation time data is to turn ON one or more beams, or when corresponding irradiation time data is to turn OFF all the beams. When the sub shot is in the case of the corresponding irradiation time data making all the beams OFF, the common amplifier 55 becomes ON while the individual amplifier 46 keeps all the beams OFF.

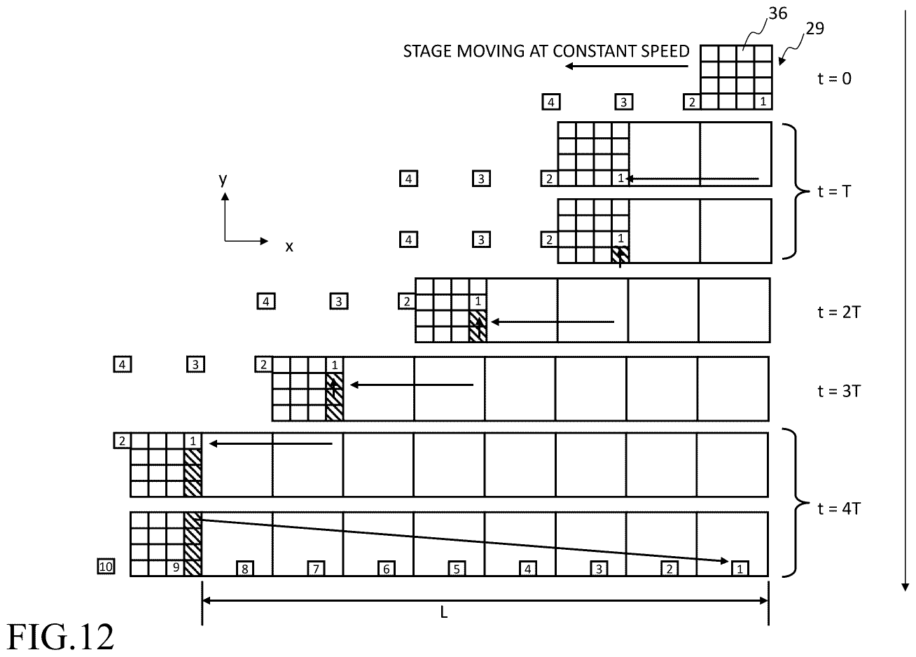

FIG. 12 is an illustration for explaining an example of a multi-beam writing operation according to the first embodiment. FIG. 12 shows the case where the inside of each sub-irradiation region 29 is written with four different beams. Furthermore, the example of FIG. 6 shows a writing operation where the XY stage 105 continuously moves at the speed at which it moves the distance L of eight beam pitches during a ¼ region, namely the region of 1/(the number of beams used for irradiation), in each sub-irradiation region 29 being written. In the writing operation shown in FIG. 12, for example, while the XY stage 105 moves the distance L of eight beam pitches, different four pixels in the same sub-irradiation region 29 are written (exposed) by being applied with four shots of the multiple beams 20 at a shot cycle T with shifting the irradiation position (pixel 36) in order by the sub deflector 209. In order that the relative position between the irradiation region 34 and the target object 101 may not be shifted by the movement of the XY stage 105 while these four pixels 36 are written (exposed), the irradiation region 34 is made to follow the movement of the XY stage 105 by collective deflection of all of the multiple beams 20 by the main deflector 208. In other words, a tracking control is performed. After one tracking cycle is completed, tracking is reset to return to the previous (last) tracking start position. Since writing of the pixels in the first column from the right of each sub-irradiation region 29 has been completed, in the next tracking cycle after resetting the tracking, first, the sub deflector 209 provides deflection such that the beam writing position is adjusted (shifted) to write the second pixel column from the right still not having been written in each sub-irradiation region 29, for example. By repeating this operation during writing the stripe region 32, as shown in the lower part of FIG. 4, the position of the irradiation region 34 of the multiple beams 20 is sequentially moved (shifted), such as the irradiation region from 34a, 34b, 34c, . . . to 34o, to perform writing.

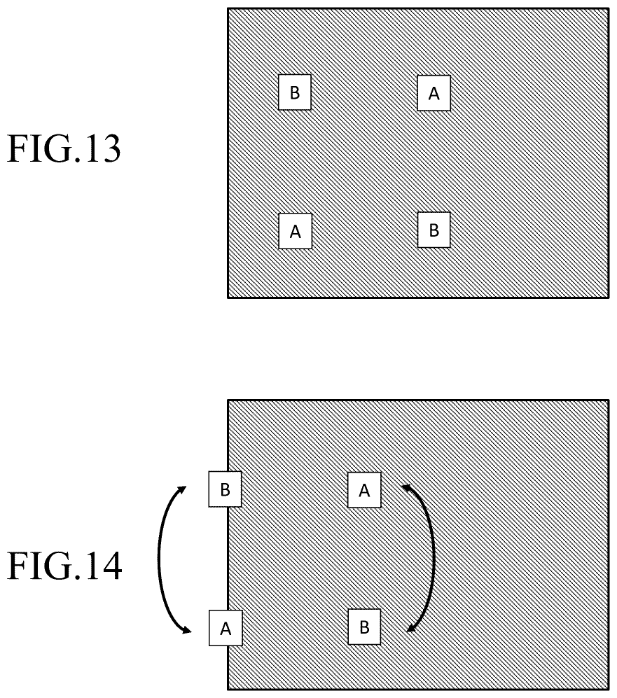

FIG. 13 is an illustration showing an example of a positional relationship between multiple electron beams and a pattern according to the first embodiment.

FIG. 14 is an illustration showing another example of the positional relationship between multiple electron beams and a pattern according to the first embodiment.

If the pixel size becomes small, as shown in FIG. 13, the case in which a plurality of pixels 36 whose number is the same as that of beams in a pattern are irradiated increases in the whole of the multiple electron beams 20. In that case, in the pixels 36 irradiated with all of the multiple electron beams 20, pixels of the group A and the pixels of the group B have the same number, for example, two here. Therefore, the pixel-set irradiation time of each pixel 36 to be irradiated is the same or close value each other in many cases. Although the area densities of pixels in a pattern are the same as each other, there is a case where doses for the pixels in the pattern have a gentle gradient due to, for example, proximity effect correction. As long as the dose gradient is gentle, both the pixel-set irradiation time of adjacent pixels 36 in pixels 36 irradiated with all of the multiple electron beams 20 inside the pattern become the same or close value each other. Particularly, if a round-off error of a real number in the case of expressing the dose by 10 bits is taken into consideration, the adjacent pixels in the pattern have substantially the same value in many cases. Therefore, the number of sub shots simultaneously becoming ON by the four beams of the groups A and B can be reduced. Furthermore, as shown in FIG. 14, there is a case where pixels irradiated with a partial beam, such as two beams, in the multiple electron beams 20 are located in the pattern, and pixels irradiated with the other beams, such as two beams, are located at the pattern edge. In that case, the two pixels located in the pattern are divided into the groups A and B. Both the pixel-set irradiation time of two pixels located inside the pattern become the same value as each other or close values in many cases. Then, similarly, the two pixels located at the pattern edge are divided into the groups A and B. Also, both the pixel-set irradiation time of two pixels located at the pattern edge become the same value as each other or close values in many cases. Therefore, the number of sub shots simultaneously becoming ON by the two beams divided into the groups A and B irradiating the pixels in the pattern can be reduced. Furthermore, at the same time, the number of sub shots simultaneously becoming ON by the two beams divided into the groups A and B irradiating the pixels at the pattern edge can be reduced. Thus, in both the cases of FIGS. 13 and 14, it is possible to reduce the number of sub shots which simultaneously become ON during a shot period of the multiple electron beams 20. Thereby, the average beam current during a shot time can be reduced.

In general, there may a case where coverages of pixels exposed with adjacent beams are different, and the number of sub shots which simultaneously become ON by adjacent beams is large. However, many of pixels individually exposed by each of multiple beams are located inside a pattern or located at the portion where no pattern exists, and the number of beams which expose pixels at the pattern edge is small. Therefore, as long as the average area density of the region exposed by one shot of a multiple beam array is comparatively uniform, the number of sub shots simultaneously becoming ON can be reduced by the method according to the present embodiment.

Although each pixel 36 is irradiated with a beam whose irradiation time is different from the original one, since doses are averaged between pixels in the same pixel-set due to an averaging effect in the space by blur (beam blur and resist blurring) larger than the distance between the pixels, the dose amount difference caused by a difference between irradiation time of the pixels is reduced. Consequently, pattern positional deviation and the like can be avoided. In particular, the averaging effect can be further increased by arranging the groups to be alternate each other with respect to the x and y directions.

As described above, according to the first embodiment, the number of ON beams during one shot period can be reduced. Thereby, the average current amount of the entire ON-beam current of beams simultaneously becoming ON can be reduced. As a result, the Coulomb effect can be reduced. Consequently, the beam resolution and/or the writing resolution can be increased.

### Second Embodiment

Although the first embodiment describes the case where the pixel-set is composed of adjacent pixels, it is not limited thereto. A second embodiment describes the case where the pixel-set is composed of pixels whose positions of writing processing of multiple writing are overlapped with each other. An example of the configuration of the writing apparatus according to the second embodiment is the same as that of FIG. 1. The flowchart showing an example of main steps of the writing method according to the second embodiment is the same as that of FIG. 8. The contents of the second embodiment are the same as those of the first embodiment except for what is particularly described below.

In the second embodiment, each pixel 36 is exposed by a plurality of shots of multiple writing. Furthermore, in the second embodiment, each pixel-set is composed of pixels whose positions of writing processing of multiple writing are overlapped with each other.

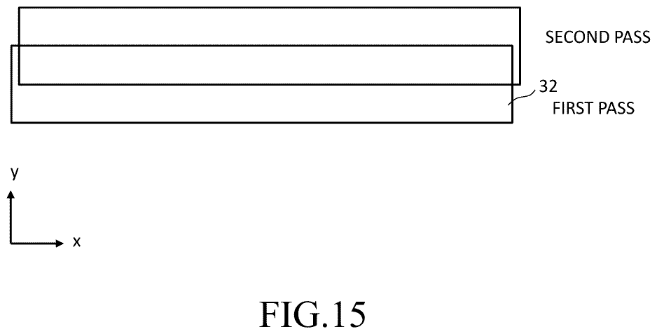

FIG. 15 is an illustration showing an example of stripe layers of passes of multiple writing according to the second embodiment. The position of the stripe region 32 of the first pass, and that of the stripe region 32 of the second pass in multiple writing are set to be shifted from each other. For example, in the case of the multiplicity N, stripe layers are shifted from each other in the y direction by 1/N of the width of the stripe region. Alternatively, they may be shifted from each other in the x direction. The case of writing the stripe region 32 by one stage movement is defined as writing processing of one pass. The case of writing the same stripe region by repeating the stage movement N times is defined as multiple writing of N passes.

Although FIG. 15 shows the case where the stripe region 32 is shifted by a position shift amount larger than the pixel size, it is not limited thereto. The stripe region 32 may be shifted by a position shift amount smaller than the pixel size. Alternatively, it is also acceptable to overlap a plurality of stripe regions 32 with each other without shifting.

In the group assignment step (S100), the group assignment processing unit 56 individually assigns one of a plurality of groups to a plurality of pixels 36 obtained by dividing the stripe region 32 (an example of a writing region) of each pass of multiple writing such that each pixel 36 and another pixel 36, which are preset to be in the same pixel-set, individually belong to different groups, that a plurality of pixels 36 irradiated by each shot of the multiple electron beams 20 include the pixels 36 of different groups, and that each pixel in the same pixel-set individually belongs to a stripe of a writing pass different from each other of the multiple writing.

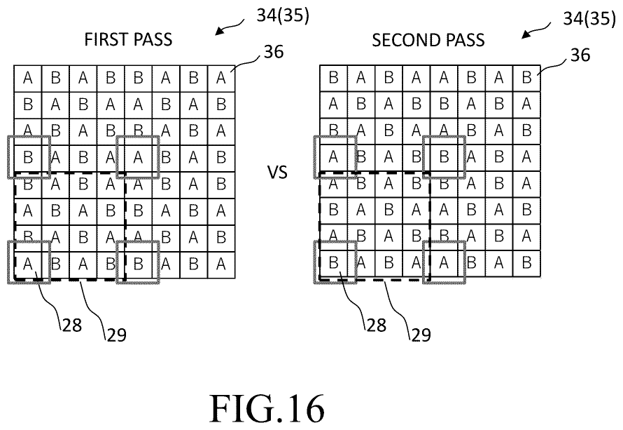

FIG. 16 is a table showing an example of an assignment of a group to a pixel according to the second embodiment.

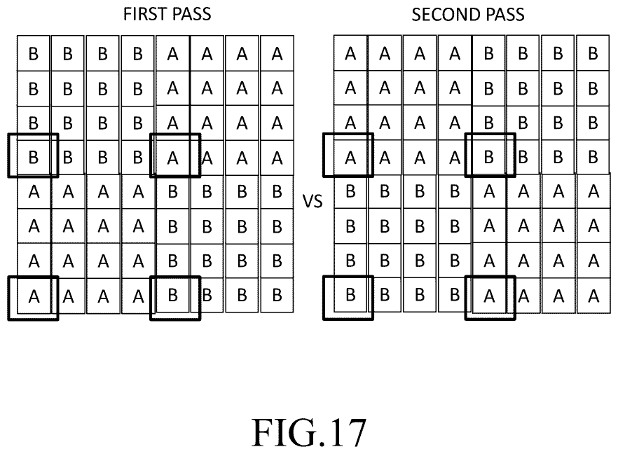

FIG. 17 is a table showing another example of an assignment of a group to a pixel according to the second embodiment.

In the examples of FIGS. 16 and 17, a pixel-set is composed of pixels 36 belonging to different stripes in a plurality of stripes used for multiple writing. For example, group assignment is performed such that a pixel belonging to the group A in the writing processing of the first pass belongs to the group B in the writing processing of the second pass. Similarly, for example, group assignment is performed such that a pixel belonging to the group B in the writing processing of the first pass belongs to the group A in the writing processing of the second pass.

Group assignment is performed such that a plurality of pixels 28 irradiated with each shot of the multiple electron beams 20 include those of different groups. FIGS. 16 and 17 show the case where group assignment is performed such that beams adjacent in the x and y directions of 2×2 multiple electron beams 20 irradiate the pixels 28 of different groups.

FIG. 16 shows, similarly to FIG. 9, the case where a plurality of groups are assigned to be alternate each other in both the x and y directions. However, the group assignment is not limited to that case. It is also preferable as shown in FIG. 17 to assign each group per sub-irradiation region 29, for example, to be alternate each other in both the x and y directions.

According to the second embodiment, since averaging is performed between passes of multiple writing, it is not necessary that the groups of adjacent pixels are different from each other. However, if group assignment is performed such that adjacent beams irradiate pixels 28 of different groups, it becomes preferable because the dose of each pass in multiple writing and the distribution of ON beams in a beam array of each shot become more uniform.

The contents of each subsequent step are the same as those of the first embodiment. If positions of a pixel of the group A and a pixel of the group B, belonging to different writing stripes, are the same on the surface of the target object and overlapped with each other, the doses of the two pixels are the same. If their positions are overlapped with each other in a shifted manner, the doses of the two pixels differ in many cases. In either case, each subsequent step can be performed similarly to the first embodiment.

As described above, according to the second embodiment, even when the pixel-set is composed of pixels belonging to different passes of multiple writing, the number of ON beams during one shot period can be reduced similarly to the first embodiment. Thereby, the average current amount of the entire ON-beam current of beams simultaneously becoming ON can be reduced. As a result, the Coulomb effect can be reduced.

### Third Embodiment

A third embodiment describes a configuration where preset weighting is performed between groups. An example of the configuration of the writing apparatus according to the third embodiment is the same as that of FIG. 1. The flowchart showing an example of main steps of the writing method according to the third embodiment is the same as that of FIG. 8. The contents of the third embodiment are the same as those of the first or second embodiment except for what is particularly described below.

The contents of each step from the group assignment step (S100) to the pixel-set irradiation time calculation step (S108) are the same as those of the first embodiment.

In the sub shot assignment step (S120), the sub shot assignment processing unit 59 assigns, to the pixels 36 each assigned one group (e.g., group A) of a plurality of groups A and B, at least one sub shot preset according to a value calculated by applying a weighting (for example, 120%), which is set in advance for the one group (e.g., group A), to the pixel-set irradiation time (irradiation time or a value based on the irradiation time) set for the pixel 36 concerned, in a plurality of sub shots. Then, the sub shot assignment processing unit 59 assigns, to the pixels 36 each assigned another group (e.g., group B) of a plurality of groups A and B, at least one sub shot according to a value calculated by applying a weighting (for example, 80%), which is set in advance for the another group (e.g., group B), to the pixel-set irradiation time (irradiation time or a value based on the irradiation time) set for the pixel 36 concerned. In other words, the value calculated based on an irradiation time for assigning a sub shot to the pixel 36 belonging to one group (e.g., group A) is the value calculated by weighting which is set in advance for the one group (e.g., group A). Furthermore, the value calculated based on an irradiation time for assigning a sub shot to the pixel 36 belonging to another group (e.g., group B) is the value obtained by weighting which is set in advance for the another group (e.g., group B).

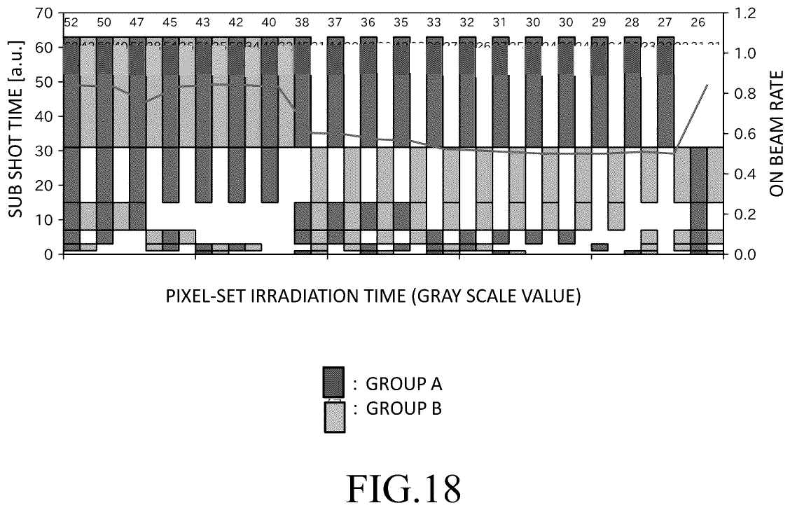

FIG. 18 is an illustration showing an example of a combination of sub shots for each partial pixel-set irradiation time according to the third embodiment.

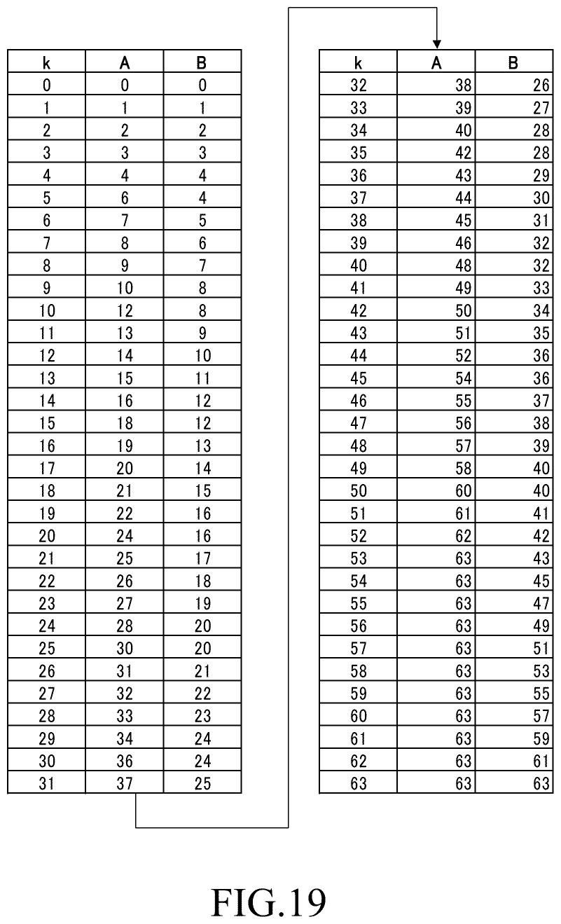

FIG. 19 is a table showing an example of an irradiation time of each group of each pixel-set irradiation time according to the third embodiment.

In FIG. 18, the ordinate axis represents a sub shot time (sub irradiation time of a sub shot), and the abscissa axis represents a pixel-set irradiation time (gray scale value)). FIG. 19 shows a combination of irradiation time of the groups A and B for each gray scale value, from k=0 to k=63, of each pixel-set irradiation time. FIG. 18 shows an example of a combination of sub shots assigned to each group, from k=26 to k=52, in the gray scale values k=0 to k=63.

According to the third embodiment, similarly to the first embodiment, for each pixel-set, at least one sub shot is assigned to each group such that the average between the total of sub irradiation time of at least one sub shot assigned to one group (e.g., group A) and the total of sub irradiation time of at least one sub shot assigned to another group (e.g., group B) becomes the pixel-set irradiation time set for each pixel 36 in the pixel-set concerned.

In the case of FIG. 19, for example, when k=0, the irradiation time is zero. For example, when k=1, since a regular weighting is difficult, a sub shot of 1Δ is set to each of the group A and the group B. For example, when k=2, since a regular weighting is difficult, a sub shot of 2Δ is set to each of the group A and the group B. For example, when k=3, since a regular weighting is difficult, a sub shot of 2Δ and a sub shot of 1Δ are set to each of the group A and the group B. For example, when k=4, since a regular weighting is difficult, a sub shot of 4Δ is set to each of the group A and the group B.

For example, when k=5, a sub shot of 4Δ and a sub shot of 2Δ are set to the group A. A sub shot of 4Δ is set to the group B. For example, when k=6, a sub shot of 4Δ, a sub shot of 2Δ, and a sub shot of 1Δ are set to the group A. A sub shot of 4Δ and a sub shot of 1Δ are set to the group B. For example, when k=7, a sub shot of 8Δ is set to the group A. A sub shot of 4Δ and a sub shot 2Δ are set to the group B.

For example, when k=27, a sub shot of 32Δ is set to the group A. A sub shot of 16Δ, a sub shot of 4Δ, and a sub shot of 2Δ are set to the group B.

For example, when k=29, a sub shot of 32Δ and a sub shot of 2Δ are set to the group A. A sub shot of 16Δ and a sub shot of 8Δ are set to the group B.

For example, when k=37, a sub shot of 32Δ, a sub shot of 8Δ, and a sub shot of 4Δ are set to the group A. A sub shot of 16Δ, a sub shot of 8Δ, a sub shot of 4Δ, and a sub shot of 2Δ are set to the group B.

For example, when k=40, a sub shot of 32Δ and a sub shot of 16Δ are set to the group A. A sub shot of 32Δ is set to the group B.

The contents of each subsequent step are the same as those of the first embodiment.

As described above, according to the third embodiment, even when the irradiation time of groups are different from each other due to weighting, the number of ON beams during one shot period can be reduced similarly to the first and second embodiments. Thereby, the average current amount of the entire ON-beam current of beams simultaneously becoming ON can be reduced. As a result, the Coulomb effect can be reduced.

### Fourth Embodiment

Although each of the above embodiments describes the case where pixels are divided into two groups A and B, it is not limited thereto. A fourth embodiment describes a configuration where pixels are divided into three or more groups. An example of the configuration of the writing apparatus according to the fourth embodiment is the same as that of FIG. 1. The flowchart showing an example of main steps of the writing method according to the fourth embodiment is the same as that of FIG. 8. The contents of the fourth embodiment are the same as those of one of the first, second, and third embodiments except for what is particularly described below.

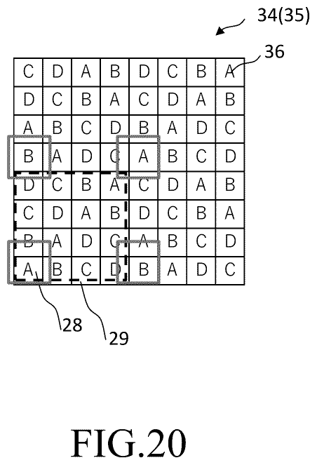

FIG. 20 is an illustration showing an example of assigning a group to a pixel according to the fourth embodiment. In FIG. 20, each pixel 36 is assigned one of four groups A, B, C, and D. Specifically, a pixel-set is composed of the groups A and B, and another pixel-set is composed of the groups C and D. In each sub-irradiation region 29, one pixel-set is composed of adjacent 2×2 pixels 36, where the groups A and B are assigned to be alternate each other in both the x and y directions. Similarly, another pixel-set is composed of adjacent 2×2 pixels 36, where the groups C and D are assigned to be alternate each other in both the x and y directions.

Group assignment is performed such that a plurality of pixels 28 irradiated with each shot of the multiple electron beams 20 include those of different groups. Specifically, in the case of irradiating the pixels 36 of the group A or B, group assignment is performed such that beams adjacent in the x and y directions of 2×2 multiple electron beams 20 irradiate the pixels 28 of different groups A and B. In the case of irradiating the pixels 36 of the group C or D, group assignment is performed such that beams adjacent in the x and y directions of 2×2 multiple electron beams 20 irradiate the pixels 28 of different groups C and D.

The table of FIG. 11 or FIG. 19 is applied to the relationship between the pixel-set irradiation time of the pixel-set of the groups A and B and the irradiation time of each group. Similarly, the table of FIG. 11 or FIG. 19 is applied to the relationship between the pixel-set irradiation time of the pixel-set of the groups C and D and the irradiation time of each group. Therefore, the relationship shown in FIG. 11 may be applied to the pixel-set of groups A and B, and the weighted relationship shown in FIG. 19 may be applied to the pixel-set of groups C and D. Alternatively, the weighted relationship of FIG. 19 may be applied to the pixel-set of groups A and B, and the weighted relationship of FIG. 19 may also be applied to the pixel-set of groups C and D. In that case, the weighting of the groups A and B, and the weighting of the groups C and D may be different from each other. For example, the weighting of the groups A and B is 120%:80%, and the weighting of the groups C and D is 115%:85%.

The other contents of the fourth embodiment are the same as those of any one of the first, second, and third embodiments.

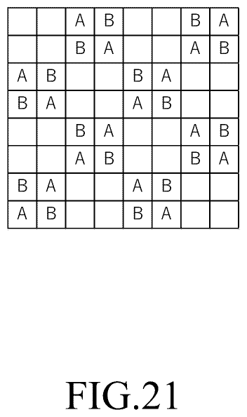

FIG. 21 is an illustration showing an example of assigning a group to a pixel according to a modified example of the fourth embodiment. In the modified example, as shown in FIG. 21, one group (blank in FIG. 21) is assigned to the pixels assigned the group C or D in FIG. 20. Therefore, pixels are divided into three groups.

Then, in the case of irradiating the pixels 36 of the group A or B, group assignment is performed such that beams adjacent in the x and y directions of 2×2 multiple electron beams 20 irradiate the pixels 28 of different groups of A and B. In the case of irradiating the pixels 36 of the other group (blank), group assignment is performed such that 2×2 multiple electron beams 20 irradiate all the pixels 36 of the other group (blank).

The table of FIG. 11 or FIG. 19 is applied to the relationship between the pixel-set irradiation time of the pixel-set of the groups A and B and the irradiation time of each group. The original irradiation time defined in an irradiation time map is applied to the other group (blank). Therefore, a combination of sub shots corresponding to the original irradiation time defined in an irradiation time map is assigned to the blank group.

The other contents of the fourth embodiment are the same as those of any one of the first, second, and third embodiments.

As described above, according to the fourth embodiment, even when pixels are divided into three or more groups, the number of ON beams during one shot period can be reduced. Thereby, the average current amount of the entire ON-beam current of beams simultaneously becoming ON can be reduced. As a result, the Coulomb effect can be reduced.

Embodiments have been explained referring to specific examples described above. However, the present invention is not limited to these specific examples. Although the examples described above describe the case where only a proximity effect is corrected, it is not limited thereto.

While the apparatus configuration, control method, and others not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Furthermore, any other multi-charged particle beam writing method, and multi-charged particle beam writing apparatus that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multi-charged particle beam writing method comprising:
assigning one of a plurality of groups to each irradiation unit region of a plurality of irradiation unit regions which are unit regions obtained by dividing a writing region of a target object to be irradiated with each beam of multiple charged particle beams, and for which a plurality of pixel-sets each composed of two and more irradiation unit regions are set in advance such that each irradiation unit region in a same pixel-set of the plurality of pixel-sets belongs to a group different from each other in the plurality of groups, and that a plurality of irradiation unit regions to be irradiated with each shot of the multiple charged particle beams include irradiation unit regions of different groups of the plurality of groups;
assigning, to an irradiation unit region assigned one group of the plurality of groups in the plurality of irradiation unit regions, at least one sub shot which has been preset according to either one of an irradiation time set for an irradiation unit region concerned in the plurality of irradiation unit regions and a value calculated based on the irradiation time, in a plurality of sub shots each having one of a plurality of sub irradiation time obtained by dividing a maximum irradiation time for one shot, and assigning, to an irradiation unit region assigned another group in the plurality of groups, at least one sub shot which includes a sub shot other than the at least one sub shot having been set for the irradiation unit region assigned the one group in the same pixel-set; and
writing, with respect to the each shot, a pattern on the target object using the multiple charged particle beams by applying at least one sub shot assigned to the each irradiation unit region of the plurality of irradiation unit regions to be irradiated with the multiple charged particle beams, wherein
with respect to each pixel-set of the plurality of pixel-sets, the at least one sub shot is assigned to the another group such that a value calculated based on a total of sub irradiation time of a preset at least one sub shot assigned to the one group and a total of sub irradiation time of the at least one sub shot assigned to the another group becomes a pixel-set irradiation time which is set for each irradiation unit region in a pixel-set concerned.

2. The method according to claim 1, wherein the each pixel-set is composed of adjacent irradiation unit regions.

3. The method according to claim 1, wherein the plurality of irradiation unit regions are individually written by a plurality of shots of multiple writing, and the each pixel-set is composed of irradiation unit regions whose positions of writing processing of the multiple writing are overlapped with each other.

4. The method according to claim 1, wherein the value calculated based on the irradiation time is a value calculated by weighting which is set in advance for the one group.

5. A multi-charged particle beam writing apparatus comprising:
a group assignment processing circuit configured to assign one of a plurality of groups to each irradiation unit region of a plurality of irradiation unit regions which are unit regions obtained by dividing a writing region of a target object to be irradiated with each beam of multiple charged particle beams, and for which a plurality of pixel-sets each composed of two and more irradiation unit regions are set in advance such that each irradiation unit region in a same pixel-set of the plurality of pixel-sets belongs to a group different from each other in the plurality of groups, and that a plurality of irradiation unit regions to be irradiated with each shot of the multiple charged particle beams include irradiation unit regions of different groups of the plurality of groups;
a sub shot assignment processing circuit configured to assign, to an irradiation unit region assigned one group of the plurality of groups in the plurality of irradiation unit regions, at least one sub shot which has been preset according to either one of an irradiation time set for an irradiation unit region concerned in the plurality of irradiation unit regions and a value calculated based on the irradiation time, in a plurality of sub shots each having one of a plurality of sub irradiation time obtained by dividing a maximum irradiation time for one shot, and to assign, to an irradiation unit region assigned another group in the plurality of groups, at least one sub shot which includes a sub shot other than the at least one sub shot having been set for the irradiation unit region assigned the one group in the same pixel-set; and
a writing mechanism configured to write, with respect to the each shot, a pattern on the target object using the multiple charged particle beams by applying at least one sub shot assigned to the each irradiation unit region of the plurality of irradiation unit regions to be irradiated with the multiple charged particle beams, wherein
the sub shot assignment processing circuit assigns, with respect to each pixel-set of the plurality of pixel-sets, the at least one sub shot to the another group such that a value calculated based on a total of sub irradiation time of a preset at least one sub shot assigned to the one group and a total of sub irradiation time of the at least one sub shot assigned to the another group becomes a pixel-set irradiation time which is set for each irradiation unit region in a pixel-set concerned.
